(19) United States
(12) Patent Application Publication
(10) Pub. No.: US 2008/0144862 A1
(43) Pub. Date: Jun. 19, 2008

(54) ALL-DIGITAL CLASS-D AUDIO AMPLIFIER WITH DIRECT BATTERY HOOK-UP

(76) Inventor: Bin Xu, Cupertino, CA (US)

Correspondence Address: Gibb & Rahman, LLC, 2568-A RIVA ROAD SUITE 304, ANNAPOLIS, MD, 21401, US

(21) Appl. No.: 11/611,415

(22) Filed: Dec. 15, 2006

(51) Int. Cl. H03F 3/217

(52) U.S. Cl. 381/120; 330/251

(57) ABSTRACT

An audio system and method of generating an amplified audio signal comprises a class-D audio amplifier; and a battery directly connected to the class-D audio amplifier, wherein the direct connection between the battery and the class-D audio amplifier achieves a power efficiency greater than approximately 90%. The audio system may further comprise an analog-to-digital converter (ADC) adapted to digitize an output voltage of the battery and digital signal processing to maintain constant audio volume regardless of the battery voltage drift.

### CROSS REFERENCE TO RELATED APPLICATION

This application relates to co-pending U.S. patent applications entitled “High-Speed, High-Resolution, Low-Power Analog-to-Digital Converter” (Docket No. XU.5000), filed concurrently herewith, the contents of which in its entirety is herein incorporated by reference.

### BACKGROUND

1. Technical Field

The embodiments herein generally relate to electrical components, and, more particularly, to class-D audio amplifiers.

2. Description of the Related Art

Class-D is a switching-based audio amplifier technology and theoretically it can achieve approximately 100% power efficiency. Traditional Class-AB audio amplifiers have a much lower power efficiency. For portable devices such as MP3 players and multi-media cell phones, etc., where the battery power consumption is critical, users are motivated to use more power efficient class-D audio amplifiers to replace the current market-dominant class-AB amplifiers, which only has approximately 20-30% efficiency for portable digital audio applications.

Currently, the commercially-available class-D amplifiers are all analog-type which can only achieve high power efficiency (approximately 90%) for high-power (>10 W) application such as home theatres and flat panel televisions. For low-power portable device applications, where the power consumption is typically in the range of 10-100 mW, the analog class-D power efficiency drops to <30% due to overhead analog circuitry of analog class-D; i.e., the feedback loop filters and external digital-to-analog converter (DAC) to convert the digital input into analog input. Currently, for portable digital audio applications, there are no suitable commercial class-D audio amplifiers which can deliver high power efficiency (approximately 90%).

Furthermore, current class-D audio amplifiers require a DC-DC voltage regulator to convert battery output voltage into stable power supply voltage in order to supply the audio power. This DC-DC regulator will consume an extra approximately 10% power consumption, further lowering the overall system power efficiency of the class-D audio amplifier. As such, there remains a need for a class-D audio amplifier which can eliminate the DC-DC converter and use direct battery hook-up to supply audio power, and which will save power consumption and cost associated with a DC-DC regulator.

### SUMMARY

In view of the foregoing, an embodiment herein provides an audio system comprising a class-D audio amplifier and a battery directly connected to the class-D audio amplifier without having a DC-DC converter attached thereto, wherein the direct connection between the battery and the class-D audio amplifier achieves a power efficiency greater than approximately 90%. The audio system may further comprise an analog-to-digital converter (ADC) adapted to digitize an output voltage of the battery. Moreover, the ADC preferably comprises an analog low-pass filter adapted to only pass the low frequency audio band between approximately 0-20 khz; a PWM wave generator adapted to generate a PWM wave at a PWM wave frequency for a duration of a PWM duty cycle; a pair of metal-oxide-semiconductor field-effect transistors (MOSFETs) driven by a PWM wave derived from the PWM wave generator, wherein the pair of MOSFETs are connected directly to battery output; and a comparator attached to the analog low-pass filter, wherein the comparator is adapted to compare a value of an output voltage of the analog low-pass filter with a reference voltage at each cycle of a PWM switching frequency.

Preferably, the PWM duty cycle in the ADC decreases if the comparator outputs a digital “1” and increases if the comparator outputs a digital “0”. Also, the reference voltage is preferably a fixed reference voltage. Furthermore, the ADC is preferably adapted to digitize the output voltage of the battery into an absolute digital value. Preferably, a digital input volume is inversely scaled according to the digitized battery voltage by the ADC such that the PWM duty cycle is inversely proportional to digitized battery voltage. Moreover, the class-D audio amplifier preferably comprises a speaker; a first low dropout (LDO) regulator directly connected to the battery to supply a digital power supply voltage; a second LDO regulator directly connected to the battery to supply an analog power supply voltage; and a pair of power stage MOSFETs directly connected to an output of the battery and is adapted to produce power to drive the speaker. Preferably, a power consumption of the digital and analog power supply voltages is less than approximately 10% of an overall power consumption on the class-D audio amplifier.

Another embodiment provides a system comprising a class-D audio amplifier; a battery directly connected to the class-D audio amplifier, wherein the battery is adapted to output voltage to the class-D audio amplifier; and a control system adapted to convert the battery output voltage into stable power supply voltage for the class-D audio amplifier and achieve a power efficiency greater than approximately 90%. Preferably, the control system comprises an ADC adapted to digitize the battery output voltage. Additionally, the ADC preferably comprises an analog low-pass filter adapted to only pass the low frequency audio band between approximately 0-20 khz; a PWM wave generator adapted to generate a PWM wave at a PWM switching frequency for a duration of a PWM duty cycle; a pair of MOSFETs driven by a PWM wave derived from the PWM wave generator, wherein the pair of MOSFETs are directly connected to an output of the battery; and a comparator attached to the analog low-pass filter, wherein the comparator is adapted to compare a value of the output voltage with a reference voltage at each cycle of the PWM switching frequency.

Preferably, the reference voltage is a fixed reference voltage. Also, the ADC may be adapted to digitize the battery output voltage into an absolute digital value so that a digital input volume associated with the class-D audio amplifier is inversely scaled according to the digitized battery voltage such that the PWM duty cycle is inversely proportional to the digitized battery voltage. Furthermore, the class-D audio amplifier preferably comprises a speaker; a first LDO regulator directly connected to the battery to supply a digital power supply voltage; a second LDO regulator directly connected to the battery to supply an analog power supply voltage; and a pair of power stage MOSFETs directly connected to an output of the battery and is adapted to produce power to drive the speaker.

Another embodiment provides a method of generating an amplified audio signal, wherein the method comprises directly connecting a battery to a class-D audio amplifier without having a DC-DC converter attached thereto; sending an output voltage directly from the battery to the class-D audio amplifier; and converting the battery output voltage into a stable power supply voltage for the class-D audio amplifier, wherein the direct connection between the battery and the class-D audio amplifier achieves a power efficiency greater than approximately 90%. Moreover, the method may further comprise digitizing the battery output voltage using an ADC. Additionally, the method may further comprise configuring the ADC by passing only the low frequency audio band between approximately 0-20 khz using an analog low-pass filter; generating a PWM wave at a PWM switching frequency for a duration of a PWM duty cycle, wherein the PWM wave drives a pair of MOSFETs; outputting voltage to the pair of MOSFETs; and comparing a value of the output voltage and a reference voltage at each clock cycle of the PWM switching frequency, wherein the reference voltage is a fixed reference voltage.

Also, the method may further comprise using the ADC to digitize the battery output voltage into an absolute digital value. Preferably, a digital input volume associated with the class-D audio amplifier is inversely scaled according to the digitized battery voltage such that the PWM duty cycle is inversely proportional to the digitized battery voltage. Moreover, the method may further comprise configuring the class-D audio amplifier by directly connecting a first LDO regulator to the battery to supply a digital power supply voltage; directly connecting a second LDO regulator to the battery to supply an analog power supply voltage; and directly connecting a pair of power stage MOSFETs to an output of the battery to produce power to drive a speaker, wherein a power consumption of the digital and analog power supply voltages is less than approximately 10% of an overall power consumption on the class-D audio amplifier.

These and other aspects of the embodiments herein will be better appreciated and understood when considered in conjunction with the following description and the accompanying drawings. It should be understood, however, that the following descriptions, while indicating preferred embodiments and numerous specific details thereof, are given by way of illustration and not of limitation. Many changes and modifications may be made within the scope of the embodiments herein without departing from the spirit thereof, and the embodiments herein include all such modifications.

### BRIEF DESCRIPTION OF THE DRAWINGS

The embodiments herein will be better understood from the following detailed description with reference to the drawings, in which:

FIG. 1 illustrates an ADC according to an embodiment herein;

FIG. 2 is a graphical representation illustrating the PWM duty cycle adjustment according to the power supply voltage according to an embodiment herein;

FIG. 3 illustrates a schematic electrical diagram for a class-D amplifier with a direct battery hook-up according to an embodiment herein; and

FIG. 4 is a flow diagram illustrating a preferred method according to an embodiment herein.

### DETAILED DESCRIPTION OF PREFERRED EMBODIMENTS

The embodiments herein and the various features and advantageous details thereof are explained more fully with reference to the non-limiting embodiments that are illustrated in the accompanying drawings and detailed in the following description. Descriptions of well-known components and processing techniques are omitted so as to not unnecessarily obscure the embodiments herein. The examples used herein are intended merely to facilitate an understanding of ways in which the embodiments herein may be practiced and to further enable those of skill in the art to practice the embodiments herein. Accordingly, the examples should not be construed as limiting the scope of the embodiments herein.

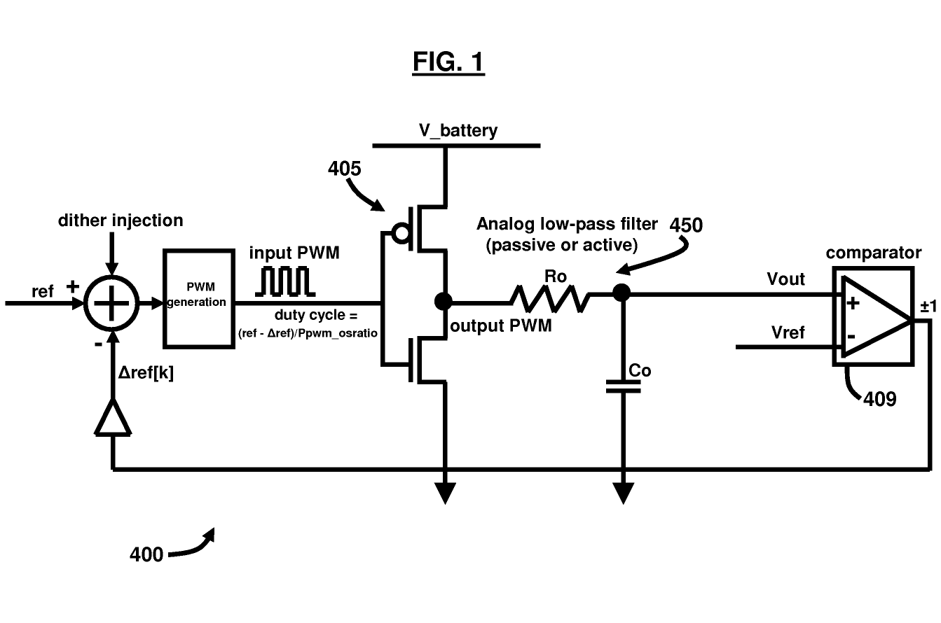

As mentioned, there remains a need for a class-D audio amplifier without using a DC-DC regulator to save power consumption and cost. The embodiments herein achieve this by providing a digital class-D audio amplifier that directly hooks up with a battery, and therefore provides an overall system power efficiency greater than approximately 90% for the class-D audio amplifier. According to the embodiments herein any rechargeable battery may be utilized. Referring now to the drawings, and more particularly to FIGS. 1 through 4, where similar reference characters denote corresponding features consistently throughout the figures, there are shown preferred embodiments.

FIG. 1 illustrates a first embodiment of a low-power ADC 400 which is capable of digitizing the battery output voltage. This ADC 400 preferably functions in accordance with the description of the ADC in co-pending U.S. patent applications entitled “High-Speed, High-Resolution, Low-Power Analog-to-Digital Converter” (Docket No. XU.5000) incorporated herein by reference, except that the Vref is provided by a fixed reference voltage; that is, the digitized battery voltage has a fixed reference, for example, a band-gap voltage reference, an external voltage, a voltage produced by low dropout (LDO), or any fixed reference voltage. The resolution of the ADC 400 does not have to be relatively high (approximately 60 dB is sufficient), and its speed does not have to be fast (approximately 1 khz is sufficient). This translates to a much lower f_{Ppwm} frequency (approximately 200 khz) and performance requirement (approximately 40 dB gain) for the comparator 409.

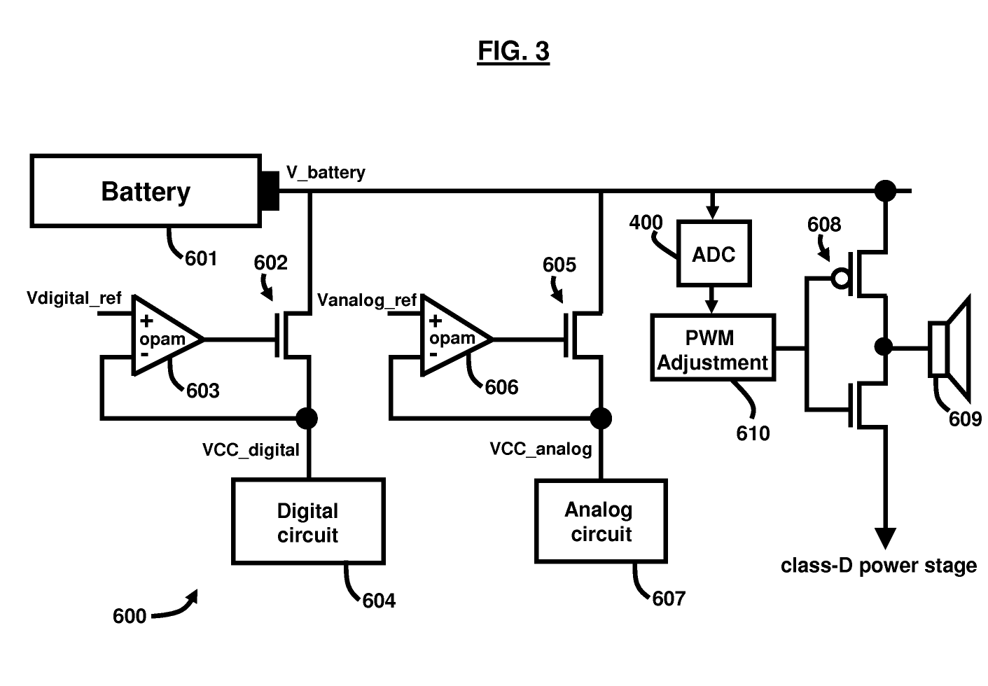

A second embodiment provides for a PWM duty cycle adjustment with the battery voltage. For rechargeable batteries, such as lithium-ion (Li-ion), the battery output voltage ranges from approximately 4.2V to 2.7V during its one-charge life cycle. To prevent audio volume drift due to battery voltage change during digital audio playback, the ADC 400 shown in FIG. 3 is used to monitor and digitize the battery output voltage into absolute digital value. This occurs using the process of obtaining ΔVCC[i] in co-pending U.S. patent applications entitled “High-Speed, High-Resolution, Low-Power Analog-to-Digital Converter” (Docket No. XU.5000) incorporated herein by reference. The digital input volume is inversely scaled according to digitized battery voltage (V_battery) by the following expression: Input volume*V_battery=constant.

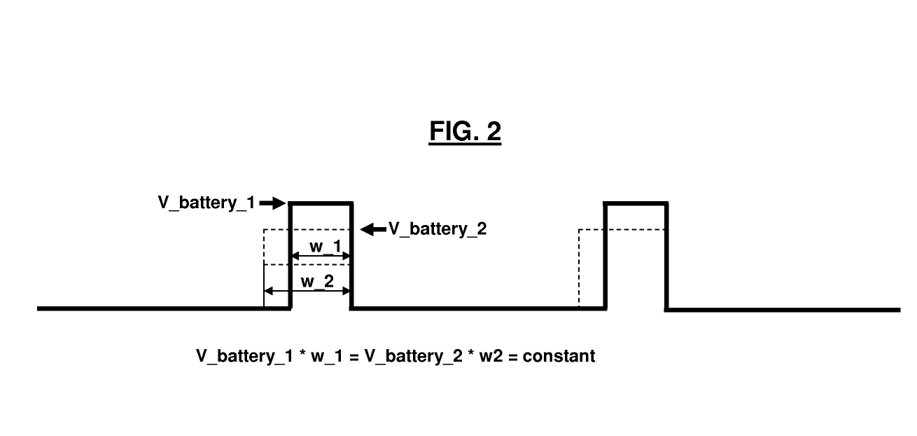

The above adjustment is performed in the digital domain. The input volume is calculated as constant/V_battery by a digital circuit. The V_battery is the digitized battery voltage by the ADC 400. Through natural sampling, the PWM duty cycle is effectively proportional to the input volume. Therefore, the expression above effectively preserves the area underneath the PWM, thus preserves the audio power regardless of the battery output voltage change, as shown in FIG. 2. This means that for a given input volume, even though the battery voltage changes, the output audio power stays the same. V_battery_1 and V_battery_2 are two voltages during the battery operation (battery constantly drain power thus its voltage keeps drifting low), measured by the ADC 400. The widths W_1 and W_2 are PWM pulse widths for the same input volume corresponding to different battery voltages at V_battery_1 and V_battery_2.

Furthermore, direct battery hook-up also allows class-D amplifiers to directly see the battery internal resistance as the power supply resistance, which is typically lower than the output resistance of DC-DC converter. Battery internal resistance is 60 mohm to 100 mohm, whereas DC-DC converter output resistance is several hundred mohm. This technique thus helps to reduce the harmonic distortions generally by approximately 10 dB-30 dB of the class-D amplifier and therefore improves the class-D audio quality because audio quality depends on the total harmonic distortion (THD).

FIG. 3 illustrates a third embodiment, which uses a LDO voltage regulator (602+603 is a LDO voltage regulator) and (605+606 is a LDO voltage regulator) to supply VCC_digital for the digital circuits 604 of the class-D amplifier 600 and VCC_analog for the analog circuits 607 of the class-D amplifier 600. Direct battery hook-up provides the power supply for audio power stage 608, but the digital circuit 604 and analog circuit 607 stills needs dedicated digital power supply and analog power supply respectively.

FIG. 3 describes how to provide power supplies for a digital class-D audio amplifier 600 with a direct battery 601 hook-up technique and using a PWM duty cycle adjustment 610 as provided by the second embodiment. There are three types of power supplies utilized. One is an audio power supply used by the class-D power stage 608 which dominants the power consumption, and it is provided by the battery 601 directly. The second is the digital circuit power supply used by all the digital circuits 604 in the all-digital class-D amplifier 600. Typically, its voltage is approximately 1-1.5V. This part of power consumption is much smaller than the audio power. The third is the analog circuit power supply used by the analog circuits 607 in the all-digital class-D amplifier 600. Typically, its voltage is approximately 1.8-3.6V. This part of power consumption is also much smaller than the audio power.

This completes all the power supply requirements of a stand alone class-D audio amplifier 600. The power efficiency of the LDO voltage regulator is low; e.g, approximately 30% for a digital power supply VCC_digital and approximately 60-80% for an analog power supply VCC_analog. However, the power consumption on the VCC_digital and the VCC_analog only accounts for less than approximately 10% of the total power consumption of the class-D amplifier 600 because the digital circuits 604 and analog circuits 607 only consume several mW, whereas the audio power consumed by the class-D power stage 608 is approximately 20-100 mW. Thus, the low-efficient LDO voltage regulator does not affect the overall power efficiency of a class-D audio amplifier 600. This correspondingly saves component cost and further optimizes power efficiency (for example, achieves a power efficiency of approximately greater than 90%), considering a DC-DC switching regulator used in battery-powered portable devices usually consumes approximately 10% of the total power consumption (approximately 20-100 mW).

The digital circuits 604 in FIG. 3 are adapted for performing digital signal processing for the all-digital class-D audio amplifier 600. For example, the digital circuits 604 may find the natural sampling point, generating the PWM waveform, and doing scaling of Input volume*V_battery=constant. The analog circuits 607 include the comparator 409 in FIG. 1, and a phase locked loop (PLL) circuit for digital clock generations.

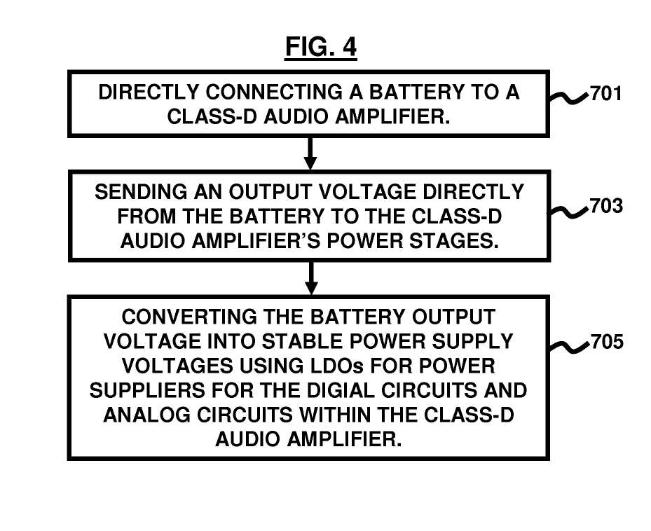

FIG. 4, with reference to FIGS. 1 through 3, is a flow diagram illustrating a method of generating an amplified audio signal according to an embodiment herein, wherein the method comprises directly connecting (701) a battery 601 to a class-D audio amplifier 600 without having a DC-DC converter attached thereto; sending (703) an output voltage directly from the battery 601 to the class-D audio amplifier 600 (power stages); and converting (705) the battery output voltage into a stable power supply voltage for the class-D audio amplifier 600 using LDOs (602+603), (605+606) for power suppliers for the digital circuits 604 and analog circuits 607 within the class-D audio amplifier 600, wherein the direct connection between the battery 601 and the class-D audio amplifier 600 achieves a power efficiency greater than approximately 90%.

The method may further comprise digitizing the battery output voltage using an ADC 400. Additionally, the method may further comprise configuring the ADC 400 by passing only the low frequency audio band between approximately 0-20 khz using an analog low-pass filter 450; generating a PWM wave at a PWM wave frequency for a duration of a PWM duty cycle, wherein the PWM wave drives a pair of MOSFETs 405; outputting voltage to the pair of MOSFETs 405; and comparing a value of the output voltage and a reference voltage at each cycle of the PWM switching frequency, wherein the reference voltage may be a fixed reference voltage.

The method may further comprise using the ADC 400 to digitize the battery output voltage into an absolute digital value. Furthermore, a digital input volume is inversely scaled according to the digitized battery voltage such that the PWM duty cycle is inversely proportional to the digitized battery voltage. Moreover, the method may further comprise configuring the class-D audio amplifier by directly connecting a first LDO regulator (602+603) to the battery 601 to supply a digital power supply voltage; directly connecting a second LDO regulator (605+606) to the battery 601 to supply an analog power supply voltage; and using a pair of MOSFETs 608 directly connected to the battery 601 to produce power to drive a speaker 609, wherein a power consumption of the digital and analog power supply voltages is less than approximately 10% of an overall power consumption on the class-D audio amplifier 600.

The techniques provided by the embodiments herein may be implemented on an integrated circuit (IC) chip or using printable electronic technologies (not shown). The chip or printable electronic circuit design is created in a graphical computer programming language, and stored in a computer storage medium (such as a disk, tape, physical hard drive, or virtual hard drive such as in a storage access network). If the designer does not fabricate chips or printable electronic circuits or the photolithographic masks used to fabricate chips or printable electronic circuits, the designer transmits the resulting design by physical means (e.g., by providing a copy of the storage medium storing the design) or electronically (e.g., through the Internet) to such entities, directly or indirectly. The stored design is then converted into the appropriate format (e.g., GDSII or CIF) for the fabrication of photolithographic masks, which typically include multiple copies of the chip design in question that are to be formed on a wafer or printed on a suitable substrate. The photolithographic masks are utilized to define areas of the wafer or printable electronic circuits (and/or the layers thereon) to be etched or otherwise processed or printed.

The resulting integrated circuit chips or printable electronic circuits can be distributed by the fabricator in raw wafer form (that is, as a single wafer that has multiple unpackaged chips), as a bare die, or in a packaged form or as individual printed circuits or in a sheet or roll of printed circuits. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip might then be integrated with other chips, discrete circuit elements, and/or other signal processing devices as part of either (a) an intermediate product, such as a mother or daughter-board, or (b) an end product. The end product can be any product that includes integrated circuit chip or chips and/or printed circuits, ranging from toys and other low-end applications to advanced computer products having a display, a keyboard or other input device, and a central processor.

The techniques provided by the embodiments herein may also be implemented on printed circuit board (PCB) using discrete components. In this case, the electronic circuit components described herein, such as adder circuit, digital IIR or FIR circuit, comparator circuit, MOSFET pair, analog low-pass filter, can use discrete components and these discrete components are electronically connected on the printed circuit board to perform the functions of the ADC 400 described herein.

The foregoing description of the specific embodiments will so fully reveal the general nature of the embodiments herein that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments herein have been described in terms of preferred embodiments, those skilled in the art will recognize that the embodiments herein can be practiced with modification within the spirit and scope of the appended claims.

What is claimed is:

1. An audio system comprising:
a class-D audio amplifier; and
a battery directly connected to said class-D audio amplifier without having a DC-DC converter attached thereto,
wherein the direct connection between said battery and said class-D audio amplifier achieves a power efficiency greater than approximately 90%.

2. The audio system of claim 1, further comprising an analog-to-digital converter (ADC) adapted to digitize an output voltage of said battery.

3. The audio system of claim 2, wherein said ADC comprises:
an analog low-pass filter adapted to only pass the low frequency audio band between approximately 0-20 khz;
a pulse-width modulation (PWM) wave generator adapted to generate a PWM wave at a PWM wave frequency for a duration of a PWM duty cycle;
a pair of metal-oxide-semiconductor field-effect transistors (MOSFETs) driven by a PWM wave derived from said PWM wave generator, wherein said pair of MOSFETs are connected directly to battery output; and
a comparator attached to said analog low-pass filter,
wherein said comparator is adapted to compare a value of an output voltage of said analog low-pass filter with a reference voltage at each cycle of a PWM switching frequency.

4. The audio system of claim 3, wherein said PWM duty cycle in said ADC decreases if said comparator outputs a digital “1” and increases if said comparator outputs a digital “0”.

5. The audio system of claim 3, wherein said reference voltage is a fixed reference voltage.

6. The audio system of claim 3, wherein said ADC is adapted to digitize said output voltage of said battery into an absolute digital value.

7. The audio system of claim 6, wherein a digital input volume is inversely scaled according to the digitized battery voltage by the ADC such that said PWM duty cycle is inversely proportional to digitized battery voltage.

8. The audio system of claim 1, wherein said class-D audio amplifier comprises:
a speaker;
a first low dropout (LDO) regulator directly connected to said battery to supply a digital power supply voltage;
a second LDO regulator directly connected to said battery to supply an analog power supply voltage; and
a pair of power stage metal-oxide-semiconductor field-effect transistors (MOSFETs) directly connected to an output of said battery and is adapted to produce power to drive said speaker.

9. The audio system of claim 8, wherein a power consumption of the digital and analog power supply voltages is less than approximately 10% of an overall power consumption on said class-D audio amplifier.

10. A system comprising:
a class-D audio amplifier;
a battery directly connected to said class-D audio amplifier, wherein said battery is adapted to output voltage to said class-D audio amplifier; and
a control system adapted to convert the battery output voltage into stable power supply voltage for said class-D audio amplifier and achieve a power efficiency greater than approximately 90%.

11. The system of claim 10, wherein said control system comprises an analog-to-digital converter (ADC) adapted to digitize said battery output voltage.

12. The system of claim 11, wherein said ADC comprises:
an analog low-pass filter adapted to only pass the low frequency audio band between approximately 0-20 khz;
a pulse-width modulation (PWM) wave generator adapted to generate a PWM wave at a PWM switching frequency for a duration of a PWM duty cycle;
a pair of metal-oxide-semiconductor field-effect transistors (MOSFETs) driven by a PWM wave derived from said PWM wave generator, wherein said pair of MOSFETs are directly connected to an output of said battery; and
a comparator attached to said analog low-pass filter,
wherein said comparator is adapted to compare a value of the output voltage with a reference voltage at each cycle of said PWM switching frequency.

13. The system of claim 12, wherein said reference voltage is a fixed reference voltage.

14. The system of claim 12, wherein said ADC is adapted to digitize said battery output voltage into an absolute digital value so that a digital input volume associated with said class-D audio amplifier is inversely scaled according to the digitized battery voltage such that said PWM duty cycle is inversely proportional to said digitized battery voltage.

15. The system of claim 10, wherein said class-D audio amplifier comprises:
a speaker;
a first low dropout (LDO) regulator directly connected to said battery to supply a digital power supply voltage;
a second LDO regulator directly connected to said battery to supply an analog power supply voltage; and
a pair of power stage metal-oxide-semiconductor field-effect transistors (MOSFETs) directly connected to an output of said battery and is adapted to produce power to drive said speaker.

16. A method of generating an amplified audio signal, said method comprising:
directly connecting a battery to a class-D audio amplifier without having a DC-DC converter attached thereto;
sending an output voltage directly from said battery to said class-D audio amplifier; and
converting the battery output voltage into a stable power supply voltage for said class-D audio amplifier,
wherein the direct connection between said battery and said class-D audio amplifier achieves a power efficiency greater than approximately 90%.

17. The method of claim 16, further comprising digitizing said battery output voltage using an analog-to-digital converter (ADC).

18. The method of claim 17, further comprising configuring said ADC by:
passing only the low frequency audio band between approximately 0-20 khz using an analog low-pass filter;
generating a pulse-width modulation (PWM) wave at a PWM switching frequency for a duration of a PWM duty cycle, wherein said PWM wave drives a pair of metal-oxide-semiconductor field-effect transistors (MOSFETs);
outputting voltage to said pair of MOSFETs; and
comparing a value of the output voltage and a reference voltage at each clock cycle of said PWM switching frequency,
wherein said reference voltage is a fixed reference voltage.

19. The method of claim 16, further comprising using said ADC to digitize said battery output voltage into an absolute digital value.

20. The method of claim 16, wherein a digital input volume associated with said class-D audio amplifier is inversely scaled according to the digitized battery voltage such that said PWM duty cycle is inversely proportional to said digitized battery voltage.

21. The method of claim 16, further comprising configuring said class-D audio amplifier by:
directly connecting a first low dropout (LDO) regulator to said battery to supply a digital power supply voltage;
directly connecting a second LDO regulator to said battery to supply an analog power supply voltage; and
directly connecting a pair of power stage metal-oxide-semiconductor field-effect transistors (MOSFETs) to an output of said battery to produce power to drive a speaker,
wherein a power consumption of the digital and analog power supply voltages is less than approximately 10% of an overall power consumption on said class-D audio amplifier.
